(19) United States
(12) Patent Application Publication
(10) Pub. No.: US 2009/0127695 A1
(43) Pub. Date: May 21, 2009

(54) SURFACE MOUNT PACKAGE WITH ENHANCED STRENGTH SOLDER JOINT

(76) Inventors: Patrick Kim, Gilbert, AZ (US); Mark A. Kuhlman, Laguna Niguel, CA (US); Yifan Guo, Aliso Viejo, CA (US); Anthony LoBianco, Irvine, CA (US); Robert W. Warren, Newport Beach, CA (US)

Correspondence Address: LOWRIE, LANDO & ANASTASI, LLP, ONE MAIN STREET, SUITE 1100, CAMBRIDGE, MA, 02142, US

(21) Appl. No.: 11/942,404

(22) Filed: Nov. 19, 2007

(51) Int. Cl. H01L 23/48; H01L 23/52; H01L 21/02

(52) U.S. Cl. 257/697; 257/779; 257/777; 438/123; 257/E23.003; 257/E23.023; 257/E21.536

(57) ABSTRACT

A substrate pad in a semiconductor package having a geometry and structure that facilitates providing a solder joint to the pad that has enhanced structural integrity and resistance to mechanical impact. The pad may include a plated metal stud that anchors the solder to the pad interface, providing a more compliant solder joint, even when lead-free solder is used.

### BACKGROUND

1. Field of Invention

The present invention relates generally to semiconductor devices and methods for fabricating the same and, more particularly, to solder joints and pad structures for surface mount semiconductor devices.

2. Discussion of Related Art

Presently, there are several semiconductor packaging techniques that are well received in the radio frequency (RF) component industry. One widely used package is the ball grid array (BGA) type package. BGA is a surface-mount package that utilizes an array of metal spheres or balls to provide external electrical interconnection to the packaged component. The balls are composed of solder, and are attached to a laminated substrate at the bottom side of the package. The die of the BGA is connected to the substrate either by wirebonding or flip-chip connection. The substrate of a BGA has internal conductive traces that route and connect the die-to-substrate bonds to the substrate-to-ball array bonds.

Referring to FIG. 1, there is illustrated one example of a BGA packaged component. The die 100 is attached to the laminated substrate 102 using a die attach 104 which may be, for example, an adhesive. In the illustrated example, connections to the die 100 are made with wirebonds 106. Solder balls 108 of the BGA are attached to conductive pads (not shown) on the underside of the laminated substrate 102 using a reflow oven, which melts the solder balls 108. Vias 110 provide electrical connection between the upper and lower surfaces of the laminated substrate 102. A mold compound 112 surrounds the component to provide protection against the environment (particularly for the fragile wirebonds 106). The BGA packaged component is attached to a circuit board 114 using a reflow oven to melt the solder balls 108. The solder balls 108 are already matched in position with their respective attachment sites on the circuit board 114 as this happens. The surface tension of the molten solder ball 108 keeps the package aligned in its proper location on the circuit board 114, until the solder cools and solidifies.

One advantage of BGA as a packaging solution for integrated circuits is its high interconnection density, i.e., the number of balls that it offers per given package volume is high. A related advantage arising from this high I/O density is the relatively small board space occupation of the packaged component. Another advantage includes lower thermal resistance between the package and the circuit board due to the relatively short distance between them, the ability to select a substrate with excellent thermal properties, and the ability to use thermally-enhancing features such as thermal vias within the substrate and thermal balls under it. In addition, the shorter path provided by the BGA between the die and the circuit board may also lead to better electrical performance, since the shorter path introduces less inductance. These and other advantages make the BGA package a common and popular package choice for many applications.

### SUMMARY OF INVENTION

As discussed above, the ball grid array (BGA) is a widely used surface-mount package that utilizes an array of solder balls to provide external electrical interconnection to the packaged component. These solder balls are attached to conductive pads on an insulative substrate using a solder reflow process. One common substrate material for a BGA package is a printed circuit board (PCB) made with organic resin. Ceramic, silicon, and other insulative materials have also been used for BGA substrates. Conventionally, printed circuit board (PCB) and substrate manufacturers have applied a flat solder mask defined BGA pad recessed in a photodefined solder mask aperture. While this type of solder joint structure has performed adequately for lead-based solder alloys and coarse pad pitch, it becomes less reliable as pitch decreases, particularly when lead-free solder alloys, which are more brittle than lead-based alloys, are used.

In many industries, including the wireless communications industry, there is an ever-present drive toward smaller and more complex devices such as, for example, smaller cellular telephones that have more features and capability. This, in turn, fuels a drive toward smaller and more complex components. Therefore, semiconductor package manufacturers seek to decrease the pitch of the BGA in order to decrease the package size and/or to increase the interconnection density of the package. In addition, growing environmental concerns and awareness are driving manufacturers toward “green” components which, in particular, do not use lead-based solder alloys. However, lead-free solder, such as the standard 95.5 Sn4Ag0.4Cu lead-free solder, is generally less compliant than are lead-based alloys, making it more difficult to achieve reliable solder joints when lead-free solder is used. To facilitate reliable packaging of small, “green” components, there is, therefore, a need for a solder joint structure with improved mechanical integrity.

Accordingly, at least one embodiment of the invention is directed to a pad structure that may facilitate formation of solder joints having improved structural integrity. More specifically, in one embodiment, a semiconductor package may comprise a substrate having a conductive pad disposed on a first surface of the substrate, a dielectric layer disposed over the first surface of the substrate and defining an opening to expose the conductive pad, and a conductive stud disposed on at least a portion of the conductive pad. The dielectric layer may have a first height and the metal stud may have a second height that may be substantially equal to or greater than first height. The conductive stud may be, for example, a metal such as copper, gold, silver, nickel, or tungsten.

In one example, the semiconductor package may be a land grid array package wherein the conductive pad includes a plurality of conductive pads, the dielectric layer defines a corresponding plurality of openings to expose each of the plurality of conductive pads, and the conductive stud includes a corresponding plurality of conductive studs, each one of the conductive studs being disposed on a corresponding one of the plurality of conductive pads. In another example, the semiconductor package may comprise a solder ball attached to the conductive stud. In this example, the semiconductor package may be a ball grid array package comprising a plurality of solder balls; wherein the conductive pad includes a plurality of conductive pads, the dielectric layer defines a corresponding plurality of openings to expose each of the plurality of conductive pads, the conductive stud includes a corresponding plurality of conductive studs, each one of the conductive studs being disposed on a corresponding one of the plurality of conductive pads, and wherein each one of the plurality of solder balls is attached to a corresponding one of the plurality of conductive studs. In another example, particularly where the conductive pad(s) may be copper, the conductive stud(s) comprises plated copper which may be finished, for example, with a copper OSP finish or nickel-gold plating. However, the conductive studs may alternatively comprise other metals, such as gold, silver, nickel or tungsten.

Another embodiment may be directed to a method of manufacture of a ball grid array semiconductor package including a substrate having a plurality of conductive pads disposed on a first surface of the substrate. The method may comprise acts of depositing metal on each of the plurality of conductive pads to extend a height of the conductive pads to a predetermined first height, depositing a dielectric layer over the first surface of the substrate such that the dielectric layer has a second height that is less than the first height, forming a plurality of openings in the dielectric layer, each opening corresponding to a location of a corresponding one of the plurality of conductive pads, and attaching a solder ball to the metal on each of the plurality of conductive pads. In one example, the act of depositing metal includes depositing copper.

According to another embodiment, packaged semiconductor component may comprise a substrate having an upper surface and a lower surface, a die attached to the upper surface of the substrate, a conductive pad disposed on the lower surface of the substrate, a conductive stud disposed over at least a portion of the conductive pad, and a solder ball attached to the conductive stud. In one example, the packaged semiconductor component may further comprise a dielectric layer disposed over the lower surface of the substrate; the dielectric layer having an opening formed therein, the opening corresponding to a location of the conductive pad. The dielectric layer may have a first height, and the conductive stud may have a second height that is, for example, greater than or equal to the first height. In one example, the conductive pad is a copper pad, and the conductive stud is therefore, a copper stud. The copper stud may comprise one of a copper OSP finish and a nickel-gold finish. Alternatively, the pad and/or the stud may comprise a metal other than copper, such as, for example, gold, silver, nickel or tungsten.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. The accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF THE DRAWINGS

Various aspects of at least one embodiment are discussed below with reference to the accompanying figures. In the figures, which are not intended to be drawn to scale, each identical or nearly identical component that is illustrated in various figures is represented by a like numeral. For purposes of clarity, not every component may be labeled in every drawing. The figures are provided for the purposes of illustration and explanation and are not intended as a definition of the limits of the invention. In the figures:

FIG. 1 is a cross-sectional diagram of one example of a conventional BGA packaged component attached to a circuit board;

FIG. 2 is a cross-sectional diagram of one example of a conventional solder joint;

FIG. 3 is a cross-sectional diagram of another example of a conventional solder joint;

FIG. 4 is a flow diagram illustrating one example of a method of manufacture of a component having improved solder joints in accordance with aspects of the invention;

FIG. 5 is a cross-sectional diagram of one example of an enhanced integrity solder joint according to aspects of the invention; and

FIG. 6 is a cross-sectional diagram of another example of an enhanced integrity solder joint according to aspects of the invention.

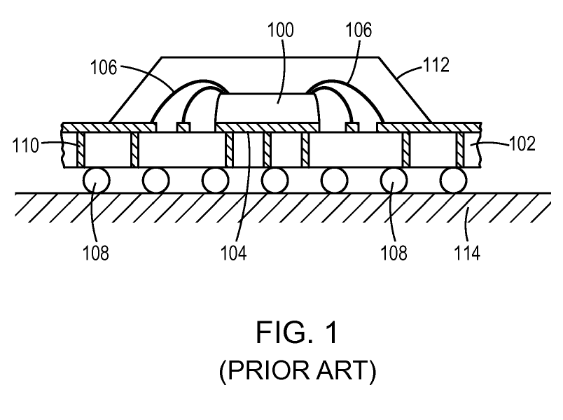

### DETAILED DESCRIPTION

As discussed above, with the semiconductor industry moving toward smaller components and the growing use of lead-free solder, there is a need for a solder joint structure with improved mechanical integrity. Accordingly, at least some aspects and embodiments are directed to a substrate pad having a plated metal stud that anchors the solder to the pad interface, as discussed below. Pads according to embodiments of the invention may have enhanced structural integrity and particularly, improved ability to withstand mechanical impact, due to the presence of the anchoring metal stud which may provide a more compliant solder joint, even when lead-free solder is used.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items.

As discussed above, the substrate of a ball grid array (BGA) package includes conductive pads to which the solder balls of the BGA are attached. These pads generally comprise plated copper. In one example, a copper pad may be finished with a plating of nickel-gold alloy. In another example, the copper pad may be finished with an organic solderability preservative (OSP). These finishes are applied to protect the underlying copper pad from oxidation and to keep the pad clean until the solder ball is attached. It is to be appreciated that although the following discussion may refer primarily to plated copper pads, the invention is not so limited and may be applied to pads comprising any conductive metal, not limited to copper. In addition, the pads may be unplated or may be finished with compounds other than nickel-gold or OSP.

During the solder reflow process used to attach the solder balls of the BGA to the substrate, intermetallic compounds are formed due to chemical reaction between the solder alloy (which usually comprises tin) and the pads. For example, in the case of a nickel-gold plated copper pad, a nickel-tin intermetallic compound may be formed. In the case of a copper-OSP pad, a copper-tin intermetallic compound may be formed. These intermetallic compounds form an interface between the unreacted metal of the pad and the solder ball.

It has been found that a conventional BGA solder joint provides a weak interface between the intermetallic compound and the pad from the standpoint of crack resistance when the component is dropped (e.g., by a user, or during a drop test used to simulate conditions that may arise during use of products in which the components are included). More specifically, it has been found that components tend to fail the drop test due to crack generation and propagation along the interface between the solder ball and the BGA pad. This indicates that the weakest interface in the BGA solder joint is between the intermetallic compound and the BGA pad on the substrate. High residual stress exists along the interface of the intermetallic compounds, mainly due to volume expansion of the intermetallic compound during the chemical reaction between the solder and the BGA pad. As a result, the intermetallic compounds are generally fairly brittle and weak and may be prone to cracking. This, in combination with the solder joint geometry, contributes to the weakness of the interface between the intermetallic compound and the BGA pad.

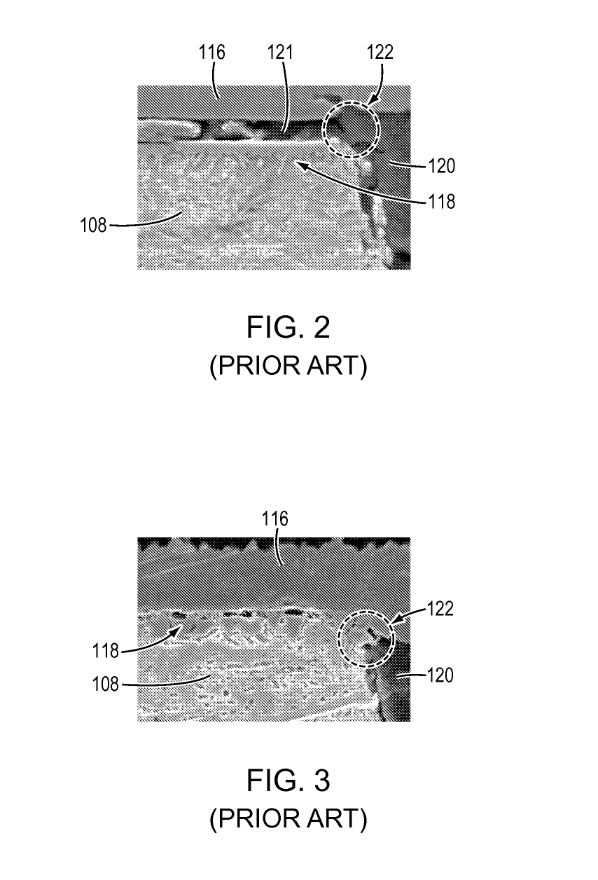

Referring to FIG. 2 there is illustrated a portion of a conventional solder joint exhibiting cracking. In this example, a copper BGA pad 116 had a nickel-gold finish, and a nickel-tin intermetallic compound 118 was formed between the pad and the solder ball 108 during attachment of the solder ball 108 to the substrate (not shown). As discussed above, the BGA pad 116 to which the solder ball 108 was attached is recessed in a photodefined aperture in the dielectric layer (e.g., a solder mask) 120. A crack 122 is clearly visible along the interface between the intermetallic compound 118 and the pad 116.

FIG. 3 illustrates another example of a conventional solder joint. In this example, the BGA pad 116 has a copper-OSP finish, and thus the intermetallic compound 118 comprised a copper-tin compound. The OSP is absorbed into the solder during the reflow and thus does not appear, at least in any great amount, in the intermetallic compound. Again, cracking is visible along the interface between the intermetallic compound 118 and the pad 116. The examples illustrated in FIGS. 2 and 3 show that the weakest point, at which cracks form during the drop test, is the interface between the intermetallic compound and the BGA pad, regardless of the finish used on the BGA substrate.

As can be seen in FIGS. 2 and 3, in a conventional BGA solder joint, the area prone to crack generation when external stress is applied is a so-called “triple point.” That is, a point where three different materials, namely the dielectric layer 120, the pad 116 and the intermetallic compound 118, meet. This triple point is illustrated in FIGS. 2 and 3 by boundary line 122. A triple point is an inherently weak structure due to the inherent internal or residual stresses caused by the joining of three different materials with different thermal characteristics and different modulus of expansion. Furthermore, the geometry of the solder joint is such that this triple point also occurs at where the metals have a relatively sharp corner, as can be seen in FIGS. 2 and 3. This geometry may make the structure even more prone to cracking when external stress is applied to the solder joint, for example, when the component (or product in which the component is being used) is dropped.

At least one embodiment of the present invention is directed to a pad structure that alters the geometry of the solder joint so as to move the weak intermetallic compound away from the high stress point, thereby strengthening the solder joint. As discussed above, in conventional pad structures, a thin plated copper pad is recessed in a well of dielectric (e.g., solder mask) 120. According to one embodiment of the invention, an additional height may be added to the base copper of the pad prior to the finish deposition, such that the surface of the pad becomes near planar with the top of the dielectric layer, or extends above the top of the layer. This additional height added to the pad is referred to herein as a “stud.” The stud may anchor the solder ball to the substrate pad, as discussed further below. In many examples where the pads on the substrate are made of copper, the stud may also comprise copper. Therefore, the following discussion may refer primarily to the use of a copper stud. However, it is to be appreciated that the invention is not so limited and the stud may comprise any of a variety of different conductive materials, including a metal other than copper, particularly in the instances where the substrate pads may be made of a metal other than copper (such as, for example, nickel, aluminum, gold, silver, or tungsten).

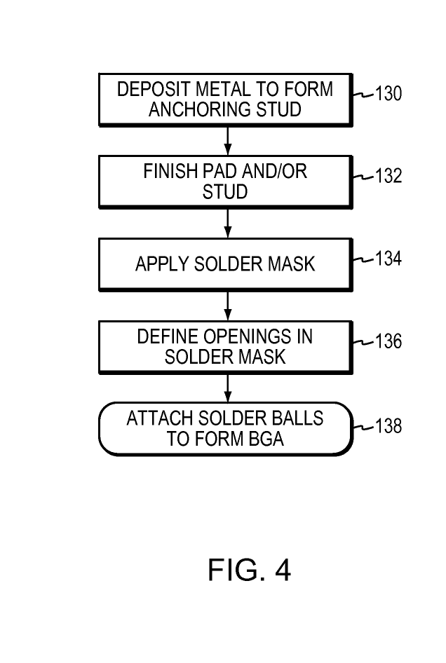

Referring to FIG. 4, there is illustrated a flow diagram of one example of a method of manufacturing a component having improved solder joints according to aspects of the invention. As discussed above, an additional height/layer of metal (e.g., copper) may be deposited on the bond pads of the substrate (step 130) to provide the anchoring stud. Also as discussed above, this step 130 may be part of the step of depositing the metal to form the bond pads on the substrate, or may be a subsequent step. The bond pad and anchoring stud may be finished (step 132) with, for example, a copper OSP or nickel-gold finish. The dielectric layer may then be applied to the substrate (step 134) and selectively removed (for example, by etching or another removal process) to define openings (step 136). If the component is to be supplied as a Land Grid Array (LGA) package, manufacture may stop at step 136. The completed LGA packaged component may later be placed on and soldered to an application board (e.g., a cell phone board or other electronic assembly board). To attach the LGA component to the application board, solder paste may be applied to bond pads on the application board, and the component positioned such that the LGA pads are in alignment and contact with the solder paste on bonds pads of the application board. A solder reflow process or wave solder process, for example, may be used to bond the component to the application board. If the component is to be supplied as a BGA package, the solder balls of the BGA may be attached to the pads in step 138. The BGA packaged component may subsequently be attached to an application board by applying solder paste to the application board and aligning and soldering the BGA balls to pads of the application board in the same manner as discussed above with respect to the LGA package.

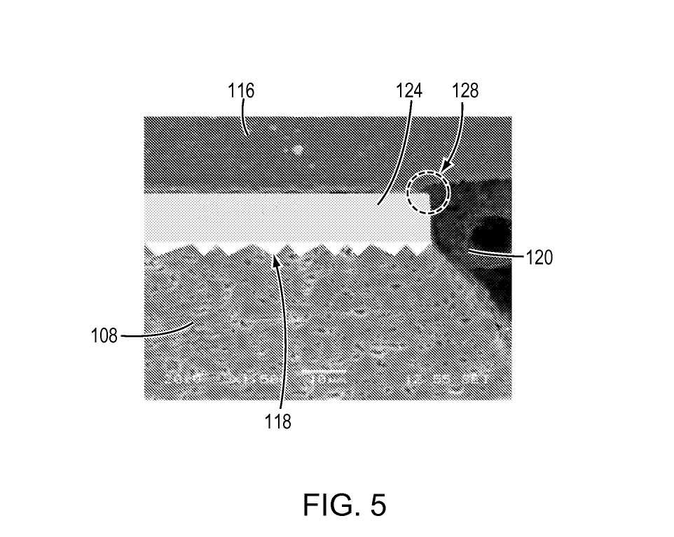

Referring to FIG. 5, there is illustrated one example of an enhanced integrity solder joint according to aspects of the invention. A plated copper stud 124 is attached to the copper pad 116. In the illustrated example, the copper stud 124 is shown as a separate element from the copper pad 116. However, in at least some examples, the copper stud 124 may be formed, either during pad formation or afterwards, by depositing additional copper in the pad area. The stud may thus be indistinguishable from the pad itself, appearing as a raised pad. The height of the copper stud 124 may be selected based on the depth of the dielectric layer 120 and the desired pad geometry. The dielectric layer may comprise a solder mask, but is not limited to a solder mask, and may generally be approximately 10 to 30 micrometers (μm) thick. Therefore, in order for the stud to bring the pad surface near planar with the top of the dielectric layer or extending above the top of the dielectric layer, the stud may have a height in a range of about 5 μm to 40 μm. In at least one example, the stud may have a height in a range of about 5 μm to about 40 μm. More particularly, in at least one example, the stud may have a height of about 20 μm. However, it is to be appreciated that these heights are given as examples only, and are not intended to be limiting.

Still referring to FIG. 5, it can be seen that the intermetallic compound 118 is shifted down, away from the contact point between the dielectric layer 120 and the pad 116, by the presence of the stud 124. In region 128, the dielectric layer 120 now contacts the copper pad 116 and copper stud 124. The copper stud 124 moves the weakest interface (solder to intermetallic compound) away from the high stress point at the edge of the pad, which reduces the stress concentration at the solder to intermetallic compound interface. The highest external stress may now be applied to a new triple point 128 where the dielectric layer 120, pad 116 and stud 124 meet. In at least some embodiments, this new triple point 128 is actually a “double point” because the pad 116 and stud 124 comprise the same material, for example, copper. Thus, the weak triple point 122 (see FIGS. 2 and 3) where the dielectric layer 120, intermetallic compound 118 and pad 116 meet together in a conventional pad design has been replaced by a far stronger double point.

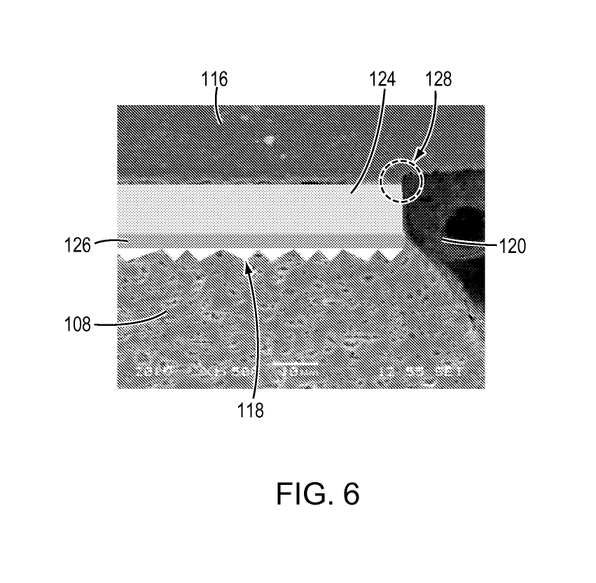

In the example illustrated in FIG. 5, the copper stud 124 is finished with OSP and therefore, the intermetallic compound 118 comprises a copper-tin compound. Referring to FIG. 6, there is illustrated another example of an enhanced integrity solder joint according to aspects of the invention. In this example, the copper stud 124 is finished with a nickel-gold plating 126 and the intermetallic compound 118 therefore comprises a nickel-tin compound. Again, the presence of the copper stud 124 moves the intermetallic compound 118 away from the high stress point, replacing the weak triple point of conventional joints with a stronger double point. Thus, regardless of the finish, the copper stud 124 serves to remove the stress initiation point caused when the pad is recessed in the dielectric layer well by extending the height of the pad 116.

The copper stud 124 may greatly improve the solder joint crack resistance, particularly when the component is dropped, due to a combination of the high mechanical integrity and ductility of the plated copper at the interface between the copper pad 116 and copper stud 124. As discussed above, the intermetallic compounds 118 are weak and often brittle, largely due to internal residual stress. By contrast, the plated copper stud 124 is mechanically strong and ductile. Thus, by replacing the weak intermetallic compound at the high stress point with the ductile copper stud 124, the solder joint is made more resistant to mechanical force. In addition, the residual stress in the double point is greatly reduced compared to that present in a triple point due to the fact that only two materials with different properties are joined, rather than three. Furthermore, moving the intermetallic compound away from the high stress point and removing the triple point reduces the total amount of stress (residual and external) applied to the weak solder-intermetallic compound interface when external stresses are applied to the BGA pad, thereby further improving the mechanical integrity of the solder joint.

Embodiments of a pad structure according to aspects of the invention may provide several advantages, including improved interfacial strength of BGA or LGA solder joints at each of the following interfaces: the interface between the nickel-gold finish on a pad and the nickel-copper-tin intermetallic compound; the interface between a plated copper pad and plated copper stud; the interface between plated copper and the copper-tin intermetallic compound; and the interface between either intermetallic compound (i.e., copper-tin or nickel-copper-tin) and solder. In addition, embodiments of pad structure according to aspects of the invention may provide a more compliant solder joint and lower stress at the intermetallic compound layer.

Embodiments discussed above have referred primarily to BGA solder joints. However, it is to be appreciated that the principles of the invention may be applied to many solder joints, not limited to BGA pads. For example, the pad structures discussed herein may also be used for land grid array (LGA) packages, as discussed above. An LGA package is similar to a BGA package, however, a completed (i.e., ready for sale) LGA packaged component does not comprise pre-attached solder balls as do BGA packaged components. Rather, conventional LGA packages have exposed finished pads, usually thin copper pads that have either an OSP or nickel-gold finish. The exposed pads are recessed within dielectric layer apertures, as discussed above. According to one embodiment, a LGA package may be provided with pads having the anchoring conductive stud discussed above. The stud may be plated, for example, with OSP or nickel-gold, to protect the stud until the component is soldered to a circuit board. The solder joint created when an LGA packaged component comprising the improved pads according to embodiments of the invention is soldered to an application board would closely resemble the solder joints illustrated in FIGS. 5 and 6. However, the size, particularly the height, of the solder 108 may be substantially reduced, as LGA packages lack the large solder balls of BGA packages. Thus, the metal stud may provide the same advantages of enhanced mechanical integrity and a more compliant solder joint for an LGA package as discussed above with respect to a BGA package.

Having thus described several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A semiconductor package comprising:
a substrate having a conductive pad disposed on a first surface of the substrate;
a dielectric layer disposed over the first surface of the substrate and defining an opening to expose the conductive pad, the dielectric layer having a first height; and
a conductive stud disposed on at least a portion of the conductive pad, the metal stud having a second height.

2. The semiconductor package as claimed in claim 1, wherein the second height is substantially equal to the first height.

3. The semiconductor package as claimed in claim 1, wherein the second height is greater than the first height.

4. The semiconductor package as claimed in claim 1, wherein the semiconductor package is a land grid array package; and
wherein the conductive pad includes a plurality of conductive pads;
wherein the dielectric layer defines a corresponding plurality of openings to expose each of the plurality of conductive pads; and
wherein the conductive stud includes a corresponding plurality of conductive studs, each one of the conductive studs being disposed on a corresponding one of the plurality of conductive pads.

5. The semiconductor package as claimed in claim 4, wherein each conductive stud of the plurality of conductive studs is a plated copper stud.

6. The semiconductor package as claimed in claim 4, wherein each conductive stud of the plurality of conductive studs comprises at least one metal selected from the group consisting of: copper, gold, silver, nickel, and tungsten.

7. The semiconductor package as claimed in claim 1, further comprising a solder ball attached to the conductive stud.

8. The semiconductor package as claimed in claim 7, wherein the semiconductor package is a ball grid array package comprising a plurality of solder balls; and
wherein the conductive pad includes a plurality of conductive pads;
wherein the dielectric layer defines a corresponding plurality of openings to expose each of the plurality of conductive pads;
wherein the conductive stud includes a corresponding plurality of conductive studs, each one of the conductive studs being disposed on a corresponding one of the plurality of conductive pads; and
wherein each one of the plurality of solder balls is attached to a corresponding one of the plurality of conductive studs.

9. The semiconductor package as claimed in claim 8, wherein the plurality of conductive studs comprises a plurality of plated copper studs.

10. The semiconductor package as claimed in claim 8, wherein the plurality of conductive studs comprises a plurality of metal studs comprising at least one metal selected from the group consisting of copper, gold, silver, nickel, and tungsten.

11. The semiconductor package as claimed in claim 1, wherein the conductive stud is a copper stud.

12. The semiconductor package as claimed in claim 11, wherein the copper stud comprises a copper OSP finish.

13. The semiconductor package as claimed in claim 11, wherein the copper stud comprises a nickel-gold finish.

14. A method of manufacture of a ball grid array semiconductor package including a substrate having a plurality of conductive pads disposed on a first surface of the substrate, the method comprising:
depositing metal on each of the plurality of conductive pads to extend a height of the conductive pads to a predetermined first height;
depositing a dielectric layer over the first surface of the substrate such that the dielectric layer has a second height that is less than the first height;
forming a plurality of openings in the dielectric layer, each opening corresponding to a location of a corresponding one of the plurality of conductive pads; and
attaching a solder ball to the metal on each of the plurality of conductive pads.

15. The method as claimed in claim 14, wherein depositing metal includes depositing copper.

16. The method as claimed in claim 14, wherein depositing the dielectric layer includes depositing a solder mask; and wherein forming a plurality of openings in the dielectric layer includes forming the plurality of openings in the solder mask.

17. A packaged semiconductor component comprising:
a substrate having an upper surface and a lower surface;
a die attached to the upper surface of the substrate;
a conductive pad disposed on the lower surface of the substrate; and
a conductive stud disposed over at least a portion of the conductive pad.

18. The packaged semiconductor component further comprising a solder ball attached to the conductive stud.

19. The packaged semiconductor component as claimed in claim 17, further comprising a dielectric layer disposed over the lower surface of the substrate, the dielectric layer having an opening formed therein, the opening corresponding to a location of the conductive pad.

20. The packaged semiconductor component as claimed in claim 19, wherein the dielectric layer has a first height and the conductive stud has a second height that is at least equal to the first height.

21. The packaged semiconductor component as claimed in claim 17, wherein the conductive pad is a copper pad, and wherein the conductive stud is a copper stud.

22. The packaged semiconductor component as claimed in claim 21, wherein the copper stud comprises one of a copper OSP finish and a nickel-gold finish.

23. The packaged semiconductor component as claimed in claim 17, wherein the conductive stud comprises at least one metal selected from the group consisting of: copper, gold, silver, nickel, and tungsten.
